(19) United States
(12) Patent Application Publication
(10) Pub. No.: US 2014/0027157 A1
(43) Pub. Date: Jan. 30, 2014

(54) Device and Method for Printed Circuit Board with Embedded Cable

(71) Applicant: FutureWei Technologies, Inc., Plano, TX (US)

(72) Inventors: Fei Yu, Santa Clara, CA (US); Hang Yan, Cupertino, CA (US); Feng Gao, Shenzhen (CN)

(21) Appl. No.: 13/907,344

(22) Filed: May 31, 2013

Related U.S. Application Data
(60) Provisional application No. 61/676,216, filed on Jul. 26, 2012.

(51) Int. Cl. H05K 1/11

(52) U.S. Cl. CPC H05K 1/11
USPC 174/251

(57) ABSTRACT

A printed circuit board (PCB) includes a first dielectric layer and a differential cable structure embedded in the dielectric layer. The differential cable structure includes a first inner conductor, a second inner conductor, a dielectric surrounding portions of the first inner conductor and portions of the second inner conductor, and a ground shield surrounding the dielectric.

This application claims the benefit of U.S. Provisional Application No. 61/676,216 filed on Jul. 26, 2012, entitled “Device and Method for Printed Circuit Board with Embedded Cable,” which application is hereby incorporated herein by reference.

### TECHNICAL FIELD

The present invention relates to a device and method for a printed circuit board, and, in particular embodiments, to a device and method for a printed circuit board with embedded cable.

### BACKGROUND

Generally, a multi-wiring board (MWB) is a printed wiring board (PWB) or printed circuit board (PCB) having pre-insulated conductive (e.g., copper) wire embedded in a dielectric layer (e.g., a prepreg material). A MWB allows for cross wiring in the same interconnection layer so that the number of wires in one layer can be increased. Thus, a board with higher signal density can be manufactured with a smaller number of layers than a typical PWB having etched signal traces.

The amount of passive channel insertion loss of in a MWB depends on the materials used and the configuration of the embedded pre-insulated conductive wires. In a typical MWB, the conductive wire (typically, copper) is surrounded by a layer of insulation (e.g., a polymide), an adhesive layer (e.g., polyethylene terephthalate (PET)), and a dielectric layer (typically, a prepreg material such as FR4 epoxy resin, M6 epoxy resin, or the like). The insulation level of the metallic wire may be negatively affected by the adhesive layer and the prepreg material of the dielectric layer. Thus, the level passive channel insertion loss of the MWB may be unnecessarily high. However the materials used for the adhesive layer and the dielectric layer may be constricted by structural requirements of the MWB. Therefore, new configurations for an embedded cable are provided to allow for the use of better insulating materials and greater isolation to achieve a lower level of passive channel insertion loss.

### SUMMARY OF THE INVENTION

These and other problems are generally solved or circumvented, and technical advantages are generally achieved, by preferred embodiments of the present invention provide a device and method for printed circuit board with embedded cable.

In accordance with an embodiment, a printed circuit board (PCB) includes a first dielectric layer and a differential cable structure embedded in the dielectric layer. The differential cable structure includes a first inner conductor, a second inner conductor, a dielectric surrounding portions of the first inner conductor and portions of the second inner conductor, and a ground shield surrounding the dielectric.

In accordance with another embodiment, a circuit structure includes a core, a build-up layer over the core, and a plurality of differential cable structures in the first build-up layer. Each differential cable structure of the plurality comprises a first inner conductor, a second inner conductor, an insulator surrounding portions of the first inner conductor and portions of the second inner conductor, and a ground shield surrounding the insulator.

In accordance with yet another embodiment, a method for forming a circuit structure includes forming an adhesive layer over a core, affixing a differential cable structure to the core with the adhesive layer, and forming a dielectric layer over the differential cable structure and the core. The dielectric layer covers top and side surfaces of the differential cable structure. The differential cable structure includes a first inner conductor, a second inner conductor, an insulating material surrounding portions of the first inner conductor and portions of the second inner conductor, and a ground shield surrounding the insulating material.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a cross-sectional view of a printed circuit board in accordance with various embodiments;

FIGS. 2A-2K are cross-sectional views of intermediate stages of manufacture of a printed circuit board in accordance with various embodiments;

FIG. 3A-3C are cross-sectional views of intermediate states of manufacture of a printed circuit board in accordance with various embodiments;

FIG. 4 is a cross-sectional view of a printed circuit board in accordance with various alternative embodiments; and

FIGS. 5A and 5B are cross-sectional views of cable structures in accordance with various alternative embodiments.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Various embodiments are described in a specific context, namely a printed circuit board (PCB) and more specifically, a multi-wiring board (MWB).

Various embodiment devices and methods provide a pre-insulated pair of inner conductors surrounded by a shielding ground cover embedded in a printed circuit board (PCB). Various embodiments generally provide a high speed system with low loss. Various embodiments provide a high speed system with low passive channel insertion loss at relatively low cost. Embodiments may be implemented in devices such as backplanes, line cards, switch cards, etc., in a high speed system, such as a router, datacenter, server, etc., operating at, for example, 25 Gbps or more.

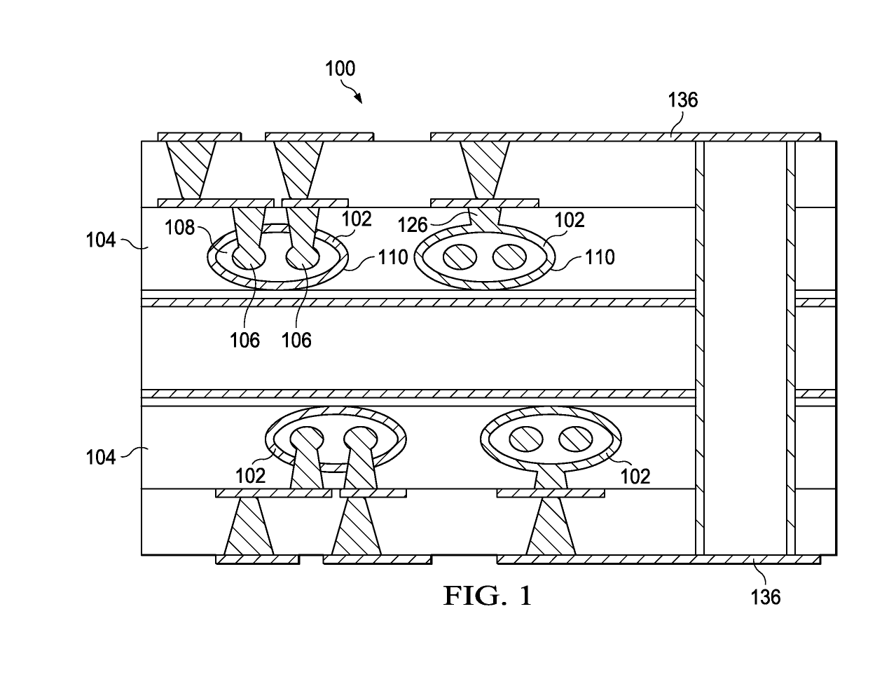

FIG. 1 illustrates a portion of a PCB 100 having pre-insulated and shielded differential cable structures 102 embedded in a build-up layer 104. Differential cable structures 102 each include a pair of inner conductors 106 surrounded by an insulating layer 108 and a ground shield 110. In various embodiments, inner conductors 106 are configured to deliver differential signals, and may be formed of a metal, for example, copper. Insulating layer 108 may be a dielectric material selected to provide very low passive-channel insertion loss, such as polytetrafluoroethylene (PTFE). Ground shields 110 are connected to PCB ground (illustrated as ground pad 136) by vias 112. Ground shields 110 isolate and better insulate inner conductors 106 from other features of PCB 100 (e.g., the material of build-up layer 104). Thus, a lower passive-channel insertion loss may be achieved. Furthermore, by including a pair of inner conductors 106 in each differential cable 102, the number of wires in a layer may be increased improving density and decreasing PCB manufacturing cost (i.e., the number of build-up layers in each PCB may be decreased).

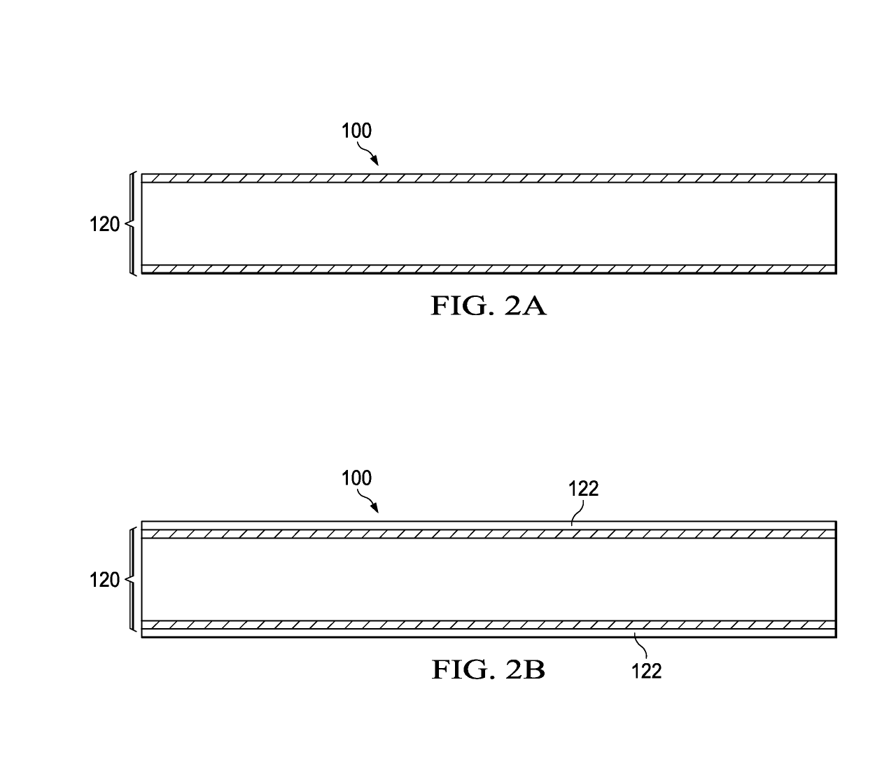

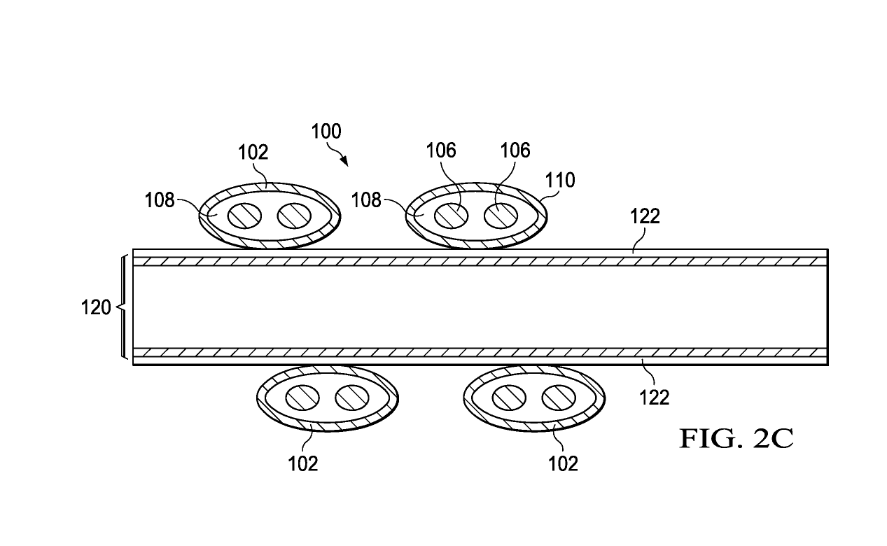

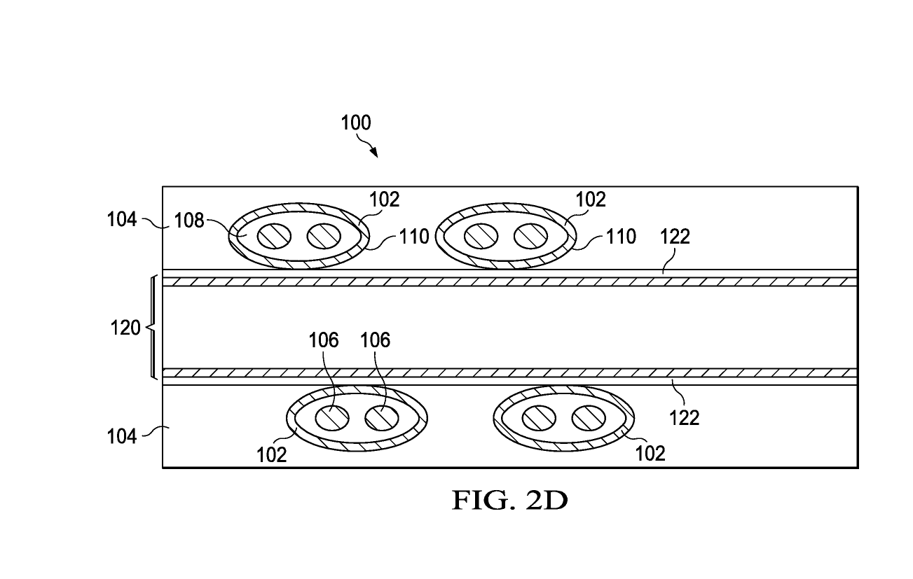

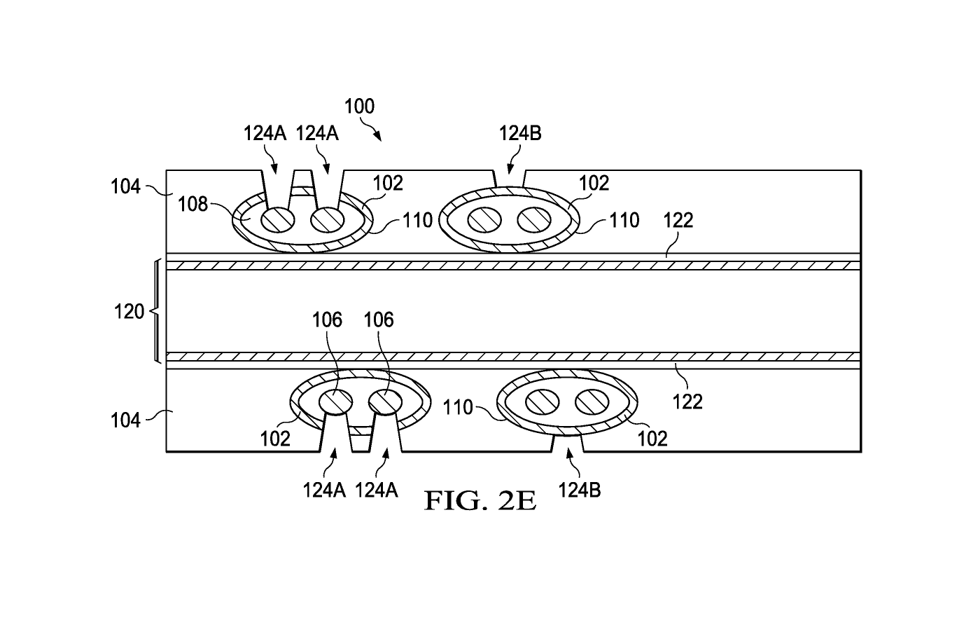

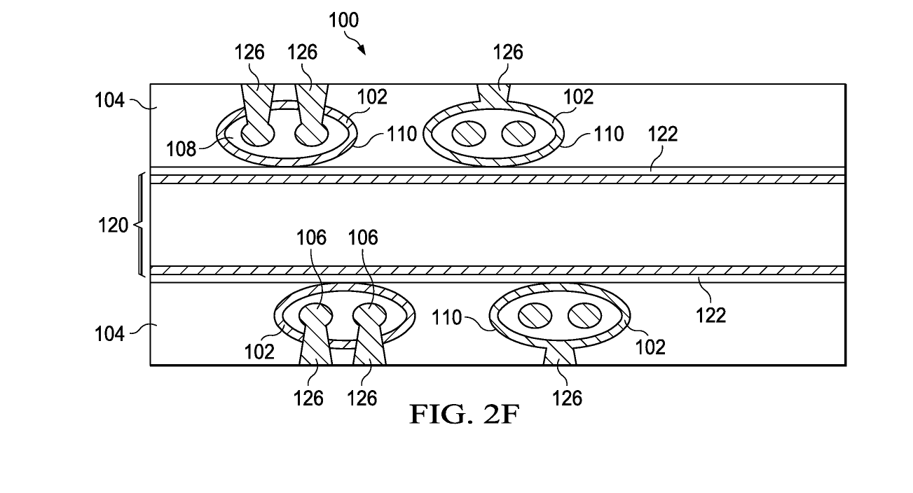

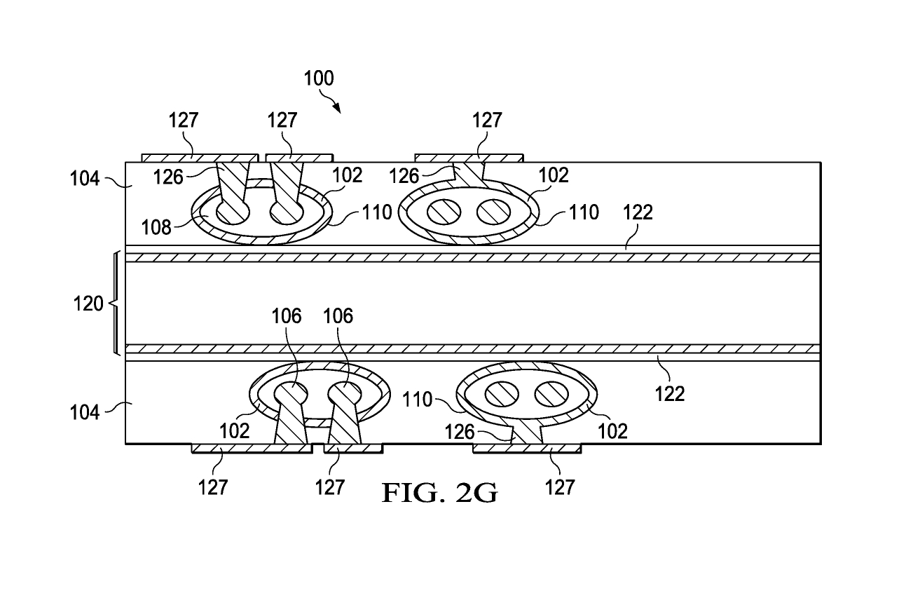

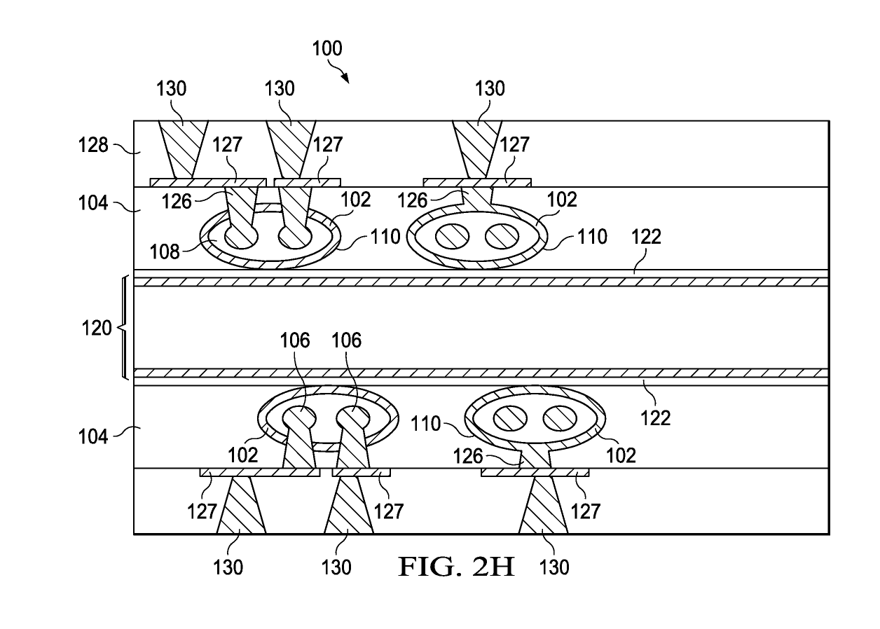

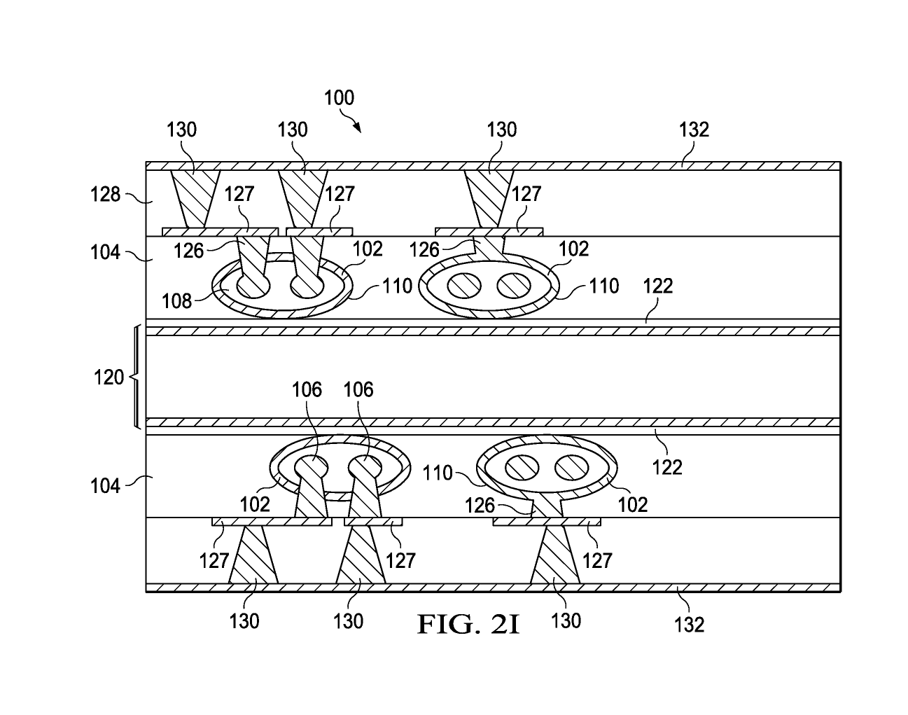

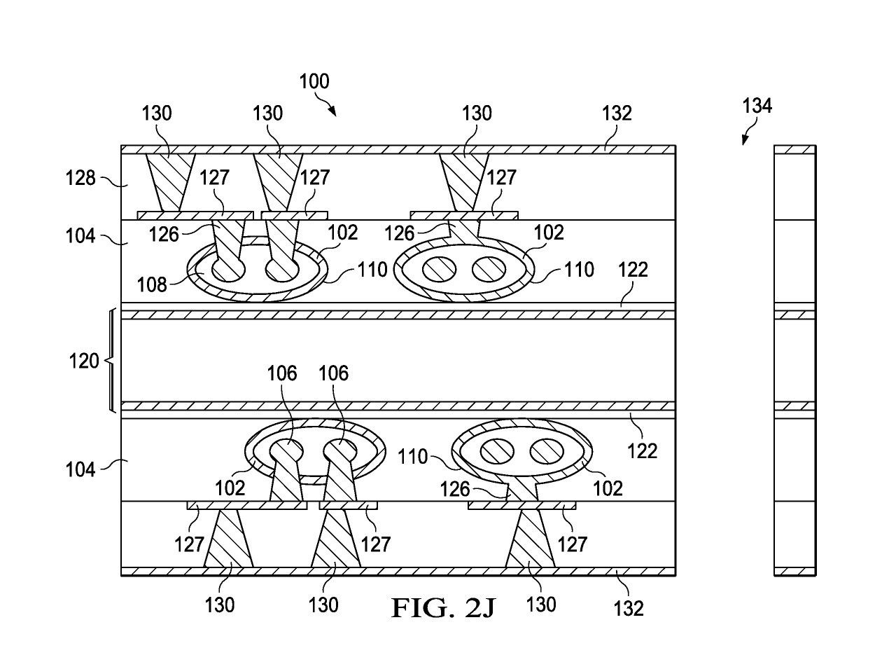

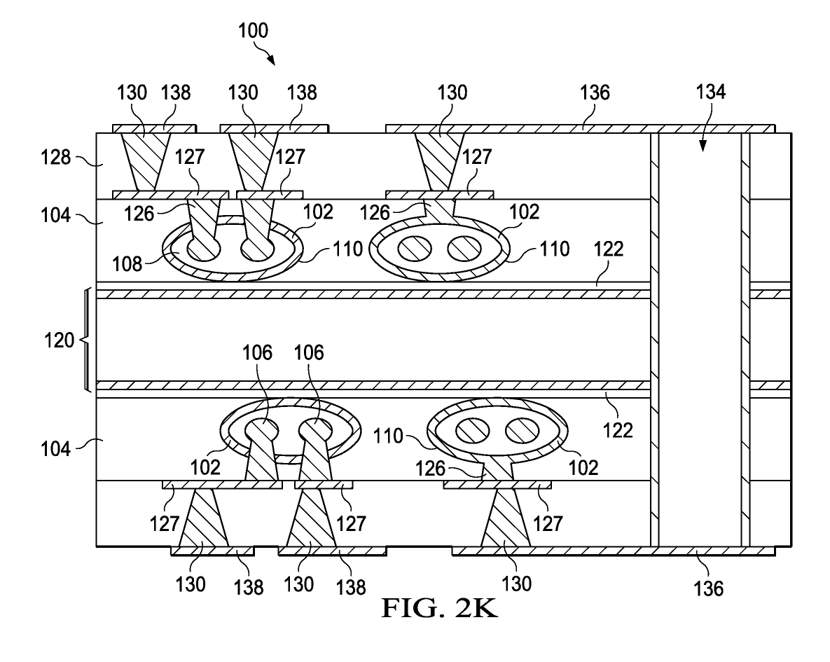

FIGS. 2A-2K illustrate cross-sectional views of intermediate stages of manufacture of PCB 100 in accordance with various embodiments. In FIG. 2A, a core 120 is provided. Core 120 may be a metal-clad insulated base material such as a copper-clad epoxy-impregnated glass-cloth laminate, a copper-clad polyimide-impregnated glass-cloth laminate, or the like. Metal portions of core 120 may be etched (not shown) to form an inner circuit layout as necessary for interconnection in PCB 100. Alternatively, core 120 may be replaced with a multi-layer circuit.

FIG. 2B illustrates the formation of adhesive layers 122 over a top and bottom surface of core 120 to affix differential cable structures 102 (see FIG. 2C) to core 120. An adhesive material (e.g., an epoxy resin) may first be coated on a carrier film (e.g., polypropylene or polyethylene terephthalate) by roll coating. A drying process is then employed to create a dry film of the adhesive material and the carrier film. The dry film is then laminated onto core 120 using a hot rolling or pressing process forming adhesive layers 122. Alternatively, adhesive layers 122 may be formed using any appropriate coating method such as spray coating, roll coating, screen printing, or the like.

FIG. 2C illustrates differential cable structures 102 embedded into adhesive layers 122. Differential cable structures 102 may be affixed onto core 120 using adhesive layers 122. For example, differential cable structures 102 may be conducted by a wiring machine applying supersonic vibrations and heat. As a result, adhesive layers 122 are softened allowing differential cable structures 102 to become embedded. Subsequently, a curing process may be applied to adhesive layers 122 so that differential cable structures 102 are secured in place.

Each differential cable structure 102 includes a pair of inner conductors 106. An insulating layer 108 surrounds and separates portions of inner conductors 106, and a ground shield 110 covers the outer surface of each differential cable structure 102. Inner conductors 106 are configured to deliver a pair of differential signals. The material of inner conductors 106 may include copper although other suitable conductors such as aluminum, tungsten, silver, gold, combinations thereof, or the like may be used as well. A small portion of inner conductors 106 may extend past the remainder of differential cable structure 102. This allows inner conductors 106 to be subsequently connected to various interconnect structures (explained in greater detail in subsequent paragraphs).

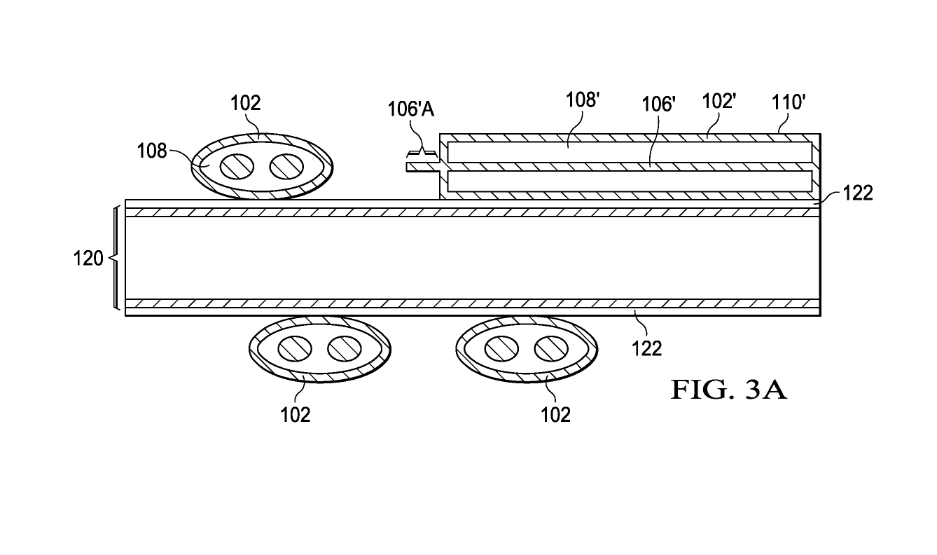

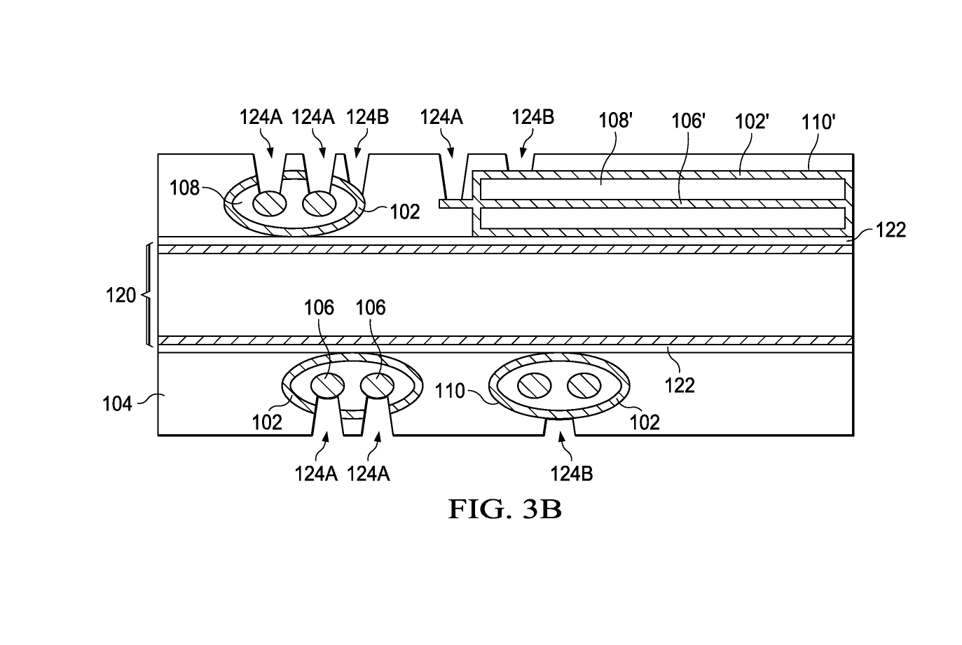

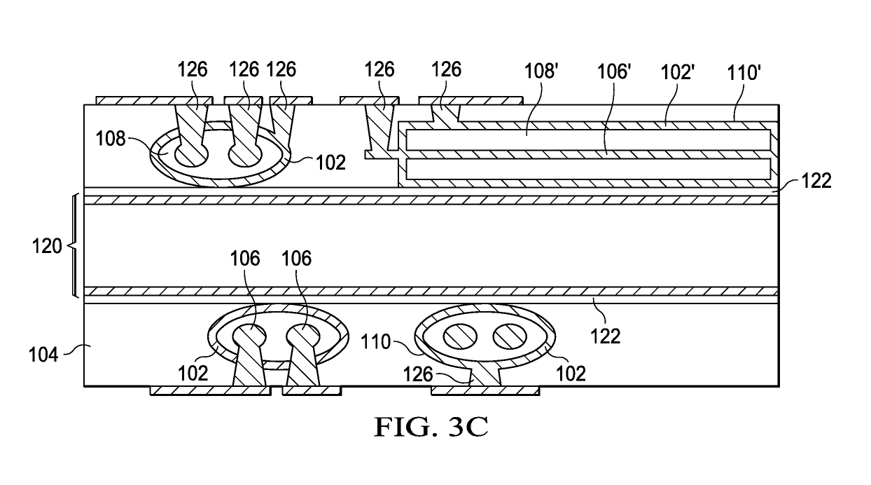

For example, FIG. 3A illustrates a cross-sectional view of a differential cable structure 102′ disposed in a direction perpendicular to other differential cable structures 102. A portion of inner conductors 106′ (i.e., portion 106′A) extends past and remains uncovered by insulating layer 108′ and ground shield 110′. Portion 106′A may be formed by removing corresponding portions of insulating layer 108′ and ground shield 110′, for example, using a wire stripping process prior to disposing differential cable structure 102′ over the adhesive layer. In various embodiments, the dimension of extended portion 106′A may be about 12 mil. However, in other embodiments, extended portion 106′A may have a different dimension depending on manufacturing capability.

Insulating layer 108 may be a dielectric material selected to provide very low passive-channel insertion loss, such as polytetrafluoroethylene (PTFE). Alternatively, a different dielectric material may be used in lieu of PTFE such as polyethylene, solid low-density polyethylene, linear low-density polyethylene, fluorinated ethylene propylene, teflon, a thermal plastic olefin blend, or the like. Grounding shield 110 may be formed of any suitable conductive material such as copper, aluminum, tungsten, silver gold, or the like. For ease of illustration, FIG. 2C illustrates differential cable structures disposed in the same direction. However, differential cable structures 102 may be disposed in varying directions (see FIG. 3A) and/or be cross wired over one each other (not shown).

FIG. 2D illustrates the formation of build-up layers 104 over differential cable structures 102. Build-up layers 104 are formed to provide protection for differential cable structures 102. Build-up layers 104 may be dielectric layers formed of a prepreg material such as FR4 epoxy resin, M6 epoxy resin, or the like. Build-up layers 104 may be laminated over differential cable structures 102, adhesive layers 122, and core 120. Subsequently, build-up layers 104 may be cured by a heat treatment or pressing if necessary. Alternatively, build-up layer may be a film layer laminated over differential cable structures 102, adhesive layers 122, and core 120.

In FIG. 2E, openings 124 (labeled as types 124A and 124B) are formed in build-up layers 104. Openings 124 extend from a top surface of build-up layer 104 and expose differential cable structures 102. Certain openings 124 (e.g., opening type 124A) expose portions of inner conductors 106. The exposed portions may be the portions of inner conductors 106 that extend past the remainder of differential cable structure 102 (see FIG. 3B). Other openings 124 (e.g., opening type 124B) expose ground shield 110 without exposing inner conductors 106. Openings 124 may be formed using a laser (e.g., a carbon dioxide laser, a yttrium aluminum garnet laser, or the like) to etch the material of build-up layer 104 and applicable portions of ground shield 110/insulating layer 108. Openings 124 may also be formed using controlled depth mechanical drilling. Alternatively, controlled depth mechanical drilling may be used in combination with laser etching to form openings 124. For example, controlled depth mechanical drilling may be used to form a first portion of openings 124 while laser etching is used to more precisely etch a remaining portion of openings 124. The use of laser etching and/or controlled depth mechanical drilling allows for precise openings to be formed in build-up layer 104. For ease of illustration, FIG. 2E shows each differential cable structure 102 exposed by either openings type 124A or 124B. However, different portions of each differential cable structure 102 may be exposed by both opening types 124A and 124B (see FIG. 3B).

In FIG. 2F, openings 124 are filled with a conductive material to form vias 126. The filling process may include electrical or chemical plating. Vias 126 may be formed of any conductive material such as copper, aluminum, tungsten, gold, or the like. Alternatively, vias 126 may be replaced with plated through holes (PTHs). For ease of illustration, differential cable structures 102 are shown as either having inner conductors 106 or ground shield 110 connected to vias 126. However, the same differential cable structure 102 may have both inner conductors 106 and ground shield 110 connected to various vias 126 (see FIG. 3C).

FIG. 2G illustrates the formation of patterned conductive lines 127 over build-up layers 104. Patterned conductive lines 127 may be formed of any conductive material such as copper foil. The formation steps of patterned conductive lines 127 may include, for example, plating or laminating solid conductive layers over build-up layers 104. Subsequently, the solid conductive layers may be patterned using, for example, photolithography and etching to form a desired conductive line pattern. Conductive lines 127 are electrically connected to vias 126.

FIG. 2H illustrates the formation of build-up layers 128 over patterned conductive lines 127 and build-up layers 104. Build-up layers 128 may be formed of substantially similar materials and methods as build-up layers 104. Build-up layers 128 further include vias 130 electrically connected to vias 126 through conductive lines 127. Vias 130 may be formed of substantially the same material and methods as vias 126. The combination of vias 130 and patterned conductive lines 127 act as interconnect structures rerouting and electrically redistributing vias 126 to other portions of PCB 100. Alternatively, build-up layers 128 and vias 130 may be omitted if electrical rerouting is not necessary. That is, these layers may be omitted if the amount of electrical interconnections desired for PCB 100 may be achieved without these layers.

FIG. 2I illustrates the formation of outer conductive layers 132. Outer conductive layers 132 may be formed, for example, of copper film laminated over build-up layers 128. FIG. 2J illustrates formation of a through hole 134, for example through drilling. Through hole 134 extends from a top surface to a bottom surface of PBC 100. FIG. 2K illustrates the plating of sidewalls of through hole 134 with a conductive material. For example, sidewalls through hole 134 may be electroless plated with copper. Through-hole 134 may also be filled with a suitable material, which may or may not be conductive. For example, a suitable non-conductive filling material may be epoxy, and a suitable conductive filling material may be copper. Subsequently, top and bottom portions of through hole 134 may be cap plated (e.g., using copper). Outer conductive layer 132 may also be patterned, for example, through etching. The patterning of outer conductive layer 132 forms ball grid array (BGA) pads 138 and ground BGA pads 136. BGA pads 138 may be heat spreader BGA pads. Ground BGA pads 136 may be referred to as common ground.

Pads 138 and 136 may be used to electrically connect PCB 100 to integrated circuits and form integrated circuit structures such as backplanes, line cards, switch cards, etc., in a high speed system (e.g., a router, datacenter, or server), or the like. Vias 126 electrically connect inner conductors 106 and ground sheild 110 to BGA pads 138 and ground BGA pads 136 respectively. Furthermore, the formation of PCB 100 may further include the formation of solder resist structures isolating BGA pads 138 and ground BGA pads 136 and the plating of pads 138 and 136 with nickel and/or aluminum (not shown). Although FIGS. 2A-2K illustrate the formation of build-up layers symmetrically over and under core 120, various alternative embodiments may also be applied to forming various features (e.g., build-up layers 104 and differential cable structures 102) unidirectionally over core 120. Furthermore, differential cable structures 102 may or may not be included both over and under core 120.

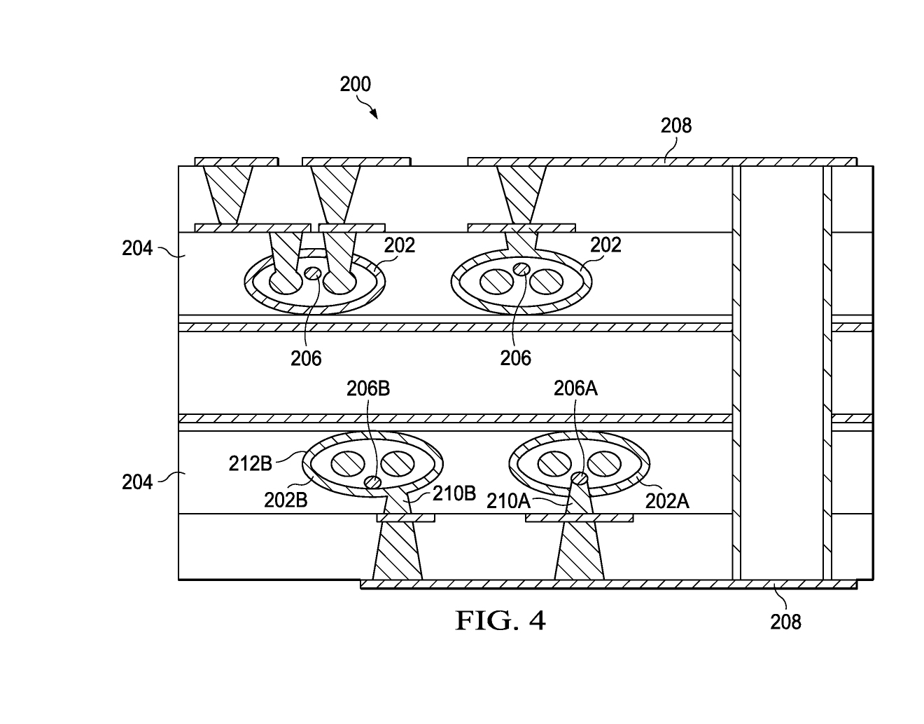

FIG. 4 illustrates a cross-sectional view of a PCB 200 in accordance with alternative embodiments. PCB 200 is substantially similar to PCB 100 of FIGS. 1 and 2A-2K, however, PCB 200 includes differential cable structures 202 embedded in build-up layer 204. Differential cable structures 202 are similar to differential cable structures 102 with the addition of a third inner conductor 206. Third inner conductor 206 may be used as a ground connection. For example, differential cable structure 202A includes a third inner conductor 206A electrically connected to ground (i.e., common ground BGA pad 208) using via 210A. Inner conductor 206A may or may not include a portion that extends outwards (not shown) from other portions of differential cable structures 202. This extended portion may be similar to portion 106′A of inner conductors 106 of differential cable structures 102 (see FIG. 3A). As another example, differential cable structure 202B includes a third inner conductor 206B electrically connected to ground shield 212B by a mechanical press connection. Ground shield 212B is connected to ground (e.g., through common ground BGA pad 208) using via 210B.

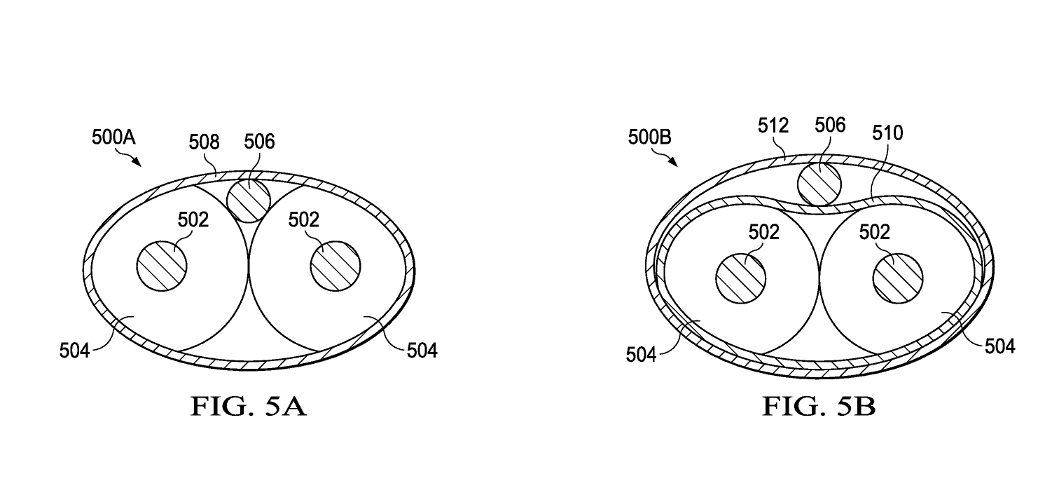

FIGS. 5A and 5B illustrate a cross-sectional view of mechanical press connections in accordance with various embodiments. In FIG. 5A and 5B, differential cable structures 500A and 500B are shown, respectively. Differential cable structures 500A and 500B may be substantially similar to differential cable structures 202 and includes a pair of inner conductors 502 surrounded by a dielectric material 504. Differential cable structures 500A and 500B further includes a third inner conductor 506. Differential cable structure 500A includes a ground shield 508 surrounding inner conductors 502, dielectric material 504, and inner conductor 506. Ground shield 508 is in physical contact with third inner conductor 506. Differential cable structure 500B includes two ground shields 510 and 512. Inner ground shield 510 surrounds inner conductors 502 and dielectric material 504. Outer ground shield 512 surrounds inner conductor 506, inner ground shield 510, dielectric material 504, and inner conductors 502 Inner conductor 506 is disposed between and contacting with inner ground shield 510 and outer ground shield 512. The materials of ground shields 508, 510, and/or 512 may be a suitable metallic material such as copper, or the like.

Various embodiments allow for lower passive channel insertion loss compared with traditional PCBs or multiwiring boards (MWBs). This is due to embodiments including inner conductors having a low-loss dielectric insulator (e.g., PTFE) surrounded by a ground shield. This configuration allows for the inner conductors to have a relatively small profile of, for example, about 0.5 μm. The configuration also allows for lower passive channel insertion loss than a single conductor without a grounding shield and having a composite polyimide, adhesive, and FR4 epoxy resin insulator.

For example, various embodiments may include a differential cable structure using a PTFE dielectric layer as an insulator and 0.5 μm copper as inner conductors. Generally, the PTFE insulator layer has a loss of about 0.06 dB/in, and the copper inner conductors have a loss of about 0.12 dB/in. Thus, a differential cable structure having this configuration will have a total loss of about 0.2 dB/in loss. This may support a theoretical total PCB link length operating at 25 Gbps of about 125 inches (i.e., 25 Gbps divided by a 0.2 dB/in loss).

Furthermore, differential cable structures may be crossed on the same layer, providing higher density and lower PCB layer count. Various embodiments provides higher density capabilities, with a smaller average pitch (i.e., the average distance between two conductors), such that a high density interconnect (HDI) structure may be sufficient to provide all the interconnections required in a PCB. Various embodiments provide a PCB board that is thinner and easier to fabricate due to the need for fewer build-up layers.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A printed circuit board (PCB) comprising:
a first dielectric layer; and
a differential cable structure embedded in the first dielectric layer, wherein the differential cable structure comprises a first inner conductor, a second inner conductor, a dielectric surrounding portions of the first inner conductor and portions of the second inner conductor, and a ground shield surrounding the dielectric.

2. The PCB of claim 1, wherein the first inner conductor and the second inner conductor are made of copper and the dielectric is polytetraflouroethylene (PTFE).

3. The PCB of claim 1, further comprising a core, wherein the first dielectric layer is formed over the core.

4. The PCB of claim 1, further comprising a first and a second conductive via electrically connecting the first inner conductor and the second inner conductor, respectively, to a first and a second ball grid array (BGA) pad on a surface of the PCB, respectively.

5. The PCB of claim 1, further comprising a third conductive via electrically connecting the ground shield to a common ground on a surface of the PCB.

6. The PCB of claim 1, wherein the differential cable structure further comprises a third inner conductor.

7. The PCB of claim 6, further comprising a fourth conductive via electrically connecting the third inner conductor to ground.

8. The PCB of claim 7, wherein the fourth conductive via is electrically connected to the ground shield, and wherein the ground shield is electrically connected to the third inner conductor with a mechanical press connection.

9. A circuit structure comprising:
a core, the core having a first and a second surface, wherein the second surface is opposite the first surface;
a first build-up layer over the first surface of the core; and
a first plurality of differential cable structures in the first build-up layer, wherein each differential cable structure of the first plurality comprises a first inner conductor, a second inner conductor, an insulator surrounding portions of the first inner conductor and portions of the second inner conductor, and a ground shield surrounding the insulator.

10. The circuit structure of claim 9, further comprising a second build-up layer on the second surface of the core; and a second plurality of differential cable structures in the second build-up layer, wherein each differential cable structure of the second plurality comprises a first inner conductor, a second inner conductor, an insulator surrounding portions of the first inner conductor and portions of the second inner conductor, and a ground shield surrounding the insulator.

11. The circuit structure of claim 9, further comprising a plurality of ball grid array (BGA) pads over the first build-up layer and the first surface of the core; and a first plurality of vias electrically connecting inner conductors of the first plurality of differential cable structures to the plurality of BGA pads.

12. The circuit structure of claim 11, further comprising a second build-up layer disposed between the first build-up layer and the plurality of BGA pads, wherein the second build-up layer comprises an interconnect structure electrically connecting the first plurality of vias to the plurality of BGA pads.

13. The circuit structure of claim 9, further comprising a common ground pad on a surface of the circuit structure; and a second plurality of vias electrically connecting ground shields of the first plurality of differential cable structures to the common ground pad.

14. The circuit structure of claim 9, wherein the first inner conductor and the second inner conductor comprise copper, and wherein the insulator is polytetraflouroethylene (PTFE).

15. The circuit structure of claim 9, wherein each differential cable structure of the first plurality further comprises a third inner conductor.

16. A method for forming a circuit structure comprising:
forming an adhesive layer over a core;
affixing a differential cable structure to the core with the adhesive layer, wherein the differential cable structure comprises a first inner conductor, a second inner conductor, an insulating material surrounding portions of the first inner conductor and portions of the second inner conductor, and a ground shield surrounding the insulating material; and
forming a dielectric layer over the differential cable structure and the core, wherein the dielectric layer covers top and side surfaces of the differential cable structure.

17. The method of claim 16, further comprising:
forming a first opening and a second opening in the dielectric layer exposing the first inner conductor and the second inner conductor, respectively;
filling the first opening and the second opening with a conductive material to form a first via and a second via, respectively;
forming a first ball grid array (BGA) pad and a second BGA pad on a surface of the circuit structure; and
electrically connecting the first BGA pad and the second BGA pad to the first inner conductor and the second inner conductor using the first via and the second via, respectively.

18. The method of claim 17, wherein forming the first opening and the second opening comprises using a laser to etch the dielectric layer.

19. The method of claim 17, wherein forming the first opening and the second opening comprises using a controlled depth mechanical drill to etch the dielectric layer.

20. The method of claim 16, further comprising electrically connecting a common ground on a surface of the circuit structure to the ground shield.
